(19) United States
(12) Patent Application Publication
(10) Pub. No.: US 2006/0239306 A1
(43) Pub. Date: Oct. 26, 2006

(54) Characterization and non-invasive correction of operational control currents of a tuneable laser

(76) Inventors: Gerry Donohoe, Dubin (IE); Neal O'gorman, Dublin (IE); Ronan O'dowd, Dublin (IE)

Correspondence Address: Timothy J Keefer;Seyfarth Shaw, 55 E Monroe Street, Chicago, IL, 60603-5863, US

(21) Appl. No.: 10/530,264

(22) PCT Filed: Oct. 9, 2003
(86) PCT No.: PCT/EP03/11201

§ 371 Date: Jun. 22, 2006

(30) Foreign Application Priority Data
Oct. 9, 2002 (GB) 0223448.2

(51) Int. Cl. H01S 3/10; H01S 3/098; H01S 3/13; H01S 3/00; H01S 5/00

(52) U.S. Cl. 372/20; 372/19; 372/50.1; 372/29.021; 372/32; 372/38.02

(57) ABSTRACT

A tuneable multi-section semiconductor laser 100 is characterized by applying currents in step-wise increments to sections 101, 102, 103 of the laser respectively and measuring power output by the laser to determine values of the applied currents corresponding to stable operating conditions for which the laser emits radiation at wavelengths remote from mode boundaries 51, 52; 141, 142 of the laser. The wavelength of the emitted radiation is measured and variations in the applied currents required to cross a mode boundary such that the laser undergoes a mode jump to emit radiation at a significantly different wavelength are also measured. These values are stored in a look-up table for use of the laser under the characterizing conditions and state of ageing of the laser. The applied currents are changed, to cause a predetermined incremental change in wavelength of the emitted radiation, within the said mode boundaries, and the further values are also stored. This is repeated for further incremental changes in wavelength. The further values may be stored in the original look-up table or in further look-up tables. The radiation emitted from the laser is monitored and the applied currents controlled by the further values whenever the output changes by a predetermined proportion of the incremental change.

This invention relates to characterization and non-invasive correction of operational control currents of a tuneable multi-section laser. Tuneable semiconductor lasers are used in, for example, telecommunications optical networks to transmit data on specified wavelength channels in a wavelength division multiplexed (WDM) system. Semiconductor lasers may be wavelength tuned for greater optical network flexibility by careful selection of control currents that cause light to be emitted at agreed wavelengths, as specified for example in the international standard ITU-G692 that covers the near infra-red spectrum.

The efficient generation of a look-up table (LUT) necessary to control the tuning of a multi-section laser for such an application is known from, for example WO 01/28052, WO 03/038954 and IE S2001/0954. The LUT is used to store values of parameters for controlling currents supplied to respective sections of the multi-section laser for which values the laser will operate stably remote from mode boundaries to emit radiation at a required frequency. There is a requirement for measurement of a quality control parameter of such lasers. Moreover, as, for example, the laser ages, or otherwise is degraded or the operating conditions change, the position of the mode boundaries may change with respect to the controlling currents, so that the laser becomes unstable by becoming subject to mode jumping and hence frequency hopping. For example, after sustained use an internal structure of crystalline material of the laser may change and the laser may require re-characterization of the currents that are stored in the LUT as a set of control currents for each lasing frequency or wavelength channel.

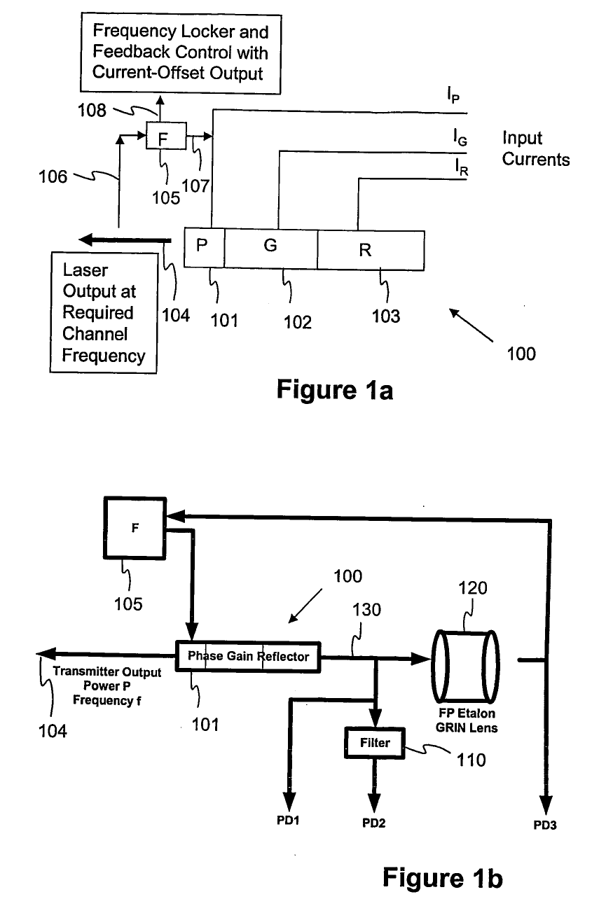

That is, with laser ageing, the lasing frequency associated with a specific combination of control currents slowly drifts. This drift can be compensated by use of a frequency locker 105, which detects frequency drift and applies corrective phase section current control as part of a wavelength locker feedback control loop, see FIGS. 1a and 1b. However, in the case of a three-section tuneable laser, there is a limit to this correction. The laser has a number of operating “modes” that correspond to various frequency channels when fine-tuned with a phase section current. The frequency locker 105 is intended to correct frequency drift within an operating mode. However, if drift is sufficiently severe, the laser may cross into another mode (i.e. mode-hop) causing a very large frequency error which is not correctable by the frequency locker.

Known methods of monitoring lasers after installation to ensure that they continue to operate stably may involve long periods of downtime. Several such schemes have been suggested to overcome laser ageing including embedding characterization software within the laser chip in order to re-characterize the laser when required, for example as disclosed in WO 03/038954 and IE S2001/0954. However, this also requires the laser to be taken out of service periodically for re-characterization of the laser.

It is desirable to use a non-invasive compensation mechanism in semiconductor laser modules to compensate for ageing that does not require down-time, i.e. removal from the network for even a short period. Such non-invasive correction of the control currents enables 100% operation of a laser for 100% of a guaranteed life span of perhaps 20 years.

It is an object of the present invention at least partially to mitigate the foregoing disadvantages.

According to a first aspect of the present invention there is provided a method of characterising a tuneable multi-section semiconductor laser comprising the steps of: a) applying currents in step-wise increments to sections of the laser respectively; b) measuring power output by the laser to determine values of the applied currents corresponding to respective stable operating conditions for which the laser emits radiation at wavelengths remote from mode boundaries of the laser; c) determining the respective wavelength of the emitted radiation; d) measuring variations in the applied currents required to cross a mode boundary such that the laser undergoes a mode jump to emit radiation at a wavelength significantly different from that under the respective stable operating condition; and e) storing in a first look-up table respective values of applied currents for which the laser emits radiation at wavelengths remote from mode boundaries, the corresponding wavelengths of the radiation and the variations in applied currents required to cross adjacent mode boundaries for use of the laser under the characterising conditions and state of ageing of the laser; and f) varying the applied currents a plurality of times, to cause predetermined incremental changes in wavelength of the emitted radiation, within the said mode boundaries, and storing further values of applied currents for each predetermined incremental change in wavelength respectively for use as the wavelength of radiation emitted with currently used applied currents changes by more than a predetermined threshold change.

Advantageously, the step of storing further values of applied currents comprises storing further look-up tables and the step of using the further values comprises using one of said further look-up tables.

Preferably, the step of storing further values of applied currents comprises storing further values corresponding to frequencies only in a predetermined range in the vicinity of predetermined required frequencies of emission of the laser.

Conveniently, the predetermined range is ±10 GHz.

Preferably, the predetermined range is ±2 GHz.

Conveniently, the further values corresponding to frequencies in the vicinity of the predetermined frequencies are stored in the first look-up table.

Conveniently, step a) comprises applying currents in step-wise increments using a programmed waveform.

Conveniently, the programmed waveform has a frequency of substantially 100 kHz.

Preferably, the programmed waveform has a frequency of substantially 1 MHz.

Conveniently, step d) of measuring the variations comprises deriving the variations by determining distances in an applied current plane of a point corresponding to the stable operating condition from adjacent longitudinal mode boundaries and, for a laser having four or more sections, from adjacent super-mode boundaries.

Advantageously, step c) includes the steps of: c1) providing an optical filter, or feature extraction filter, for transmitting a proportion of power of an incident light beam emitted by the laser, the proportion being dependant on the wavelength of the incident light beam; and c2) measuring the proportion of power transmitted by the filter to determine the wavelength of the emitted radiation.

Preferably, the optical filter comprises multiple passive optical filters.

Conveniently, the optical filter comprises a graded refractive index lens for use as a precision optical filter.

Conveniently, for a multi-section semiconductor laser having a gain section, a phase section and at least one tuning section, step a) includes the steps of: a1) applying constant currents to the gain and phase sections such that the laser emits laser radiation; and a2) applying at least one tuning current in step-wise increments to the at least one tuning section respectively; and step e) includes storing in the first look-up table the values of the at least one tuning current for which the laser emits radiation at wavelengths remote from mode boundaries.

Conveniently, for a three-section laser, the at least one tuning section comprises a reflector section.

Conveniently, for a three-section laser, step a) comprises varying a reflector current (I_{R}) to determine stable points midway between longitudinal mode boundaries.

Conveniently, for a laser having more than three sections, the at least one tuning section comprises a front section having an applied front current and a back section having an applied back current and step a) comprises holding the front current at a first front constant and varying the back current, holding the front current at a second front constant and varying the back current, holding the back current at a first back constant and varying the front current, holding the back current at a second back constant and varying the front current, and increasing the front current from a third front constant to a fourth front constant while decreasing the back current from a third back constant to a fourth back constant in order to determine stable middle lines within each super-mode and wherein, having determined the stable middle lines, subsequent steps of varying the back current and/or the front current respectively comprise varying the respective current through a window of a plurality of incremental values along the stable middle lines and determining for which of the plurality of incremental values the power output is a minimum, and repeatedly incrementing each of the plurality of incremental values and re-determining the current value corresponding to the minimum output power within the window to determine a current value corresponding to a local minimum in the power output.

Advantageously, for a laser having more than three sections, step b) comprises determining midpoints between the current values corresponding to local minima in the power output to obtain stable middle points of operation of the laser and step e) includes storing data representative of such stable middle points together with the corresponding wavelength of emitted laser light in the look-up table and operational conditions for operating the frequencies between the stable middle point frequencies are determined by determining and storing in the look-up table the required values of phase current injected into the phase section of the laser and the required values of phase current are determined by holding the back and front currents constant successively at a first stable point and incrementing the phase current until a frequency of laser emission corresponding to a next stable point is reached and calculating what increments of phase current are required to step from the first stable point to the second stable point in desired frequency increments.

According to a second aspect of the invention there is provided a method of controlling a laser characterised by any of the above method steps, and comprising the further step of: g) determining whether in use the wavelength of radiation emitted by the laser has varied from a characterising wavelength by more than a threshold variation and if so either selecting and using the further values of applied currents to restore the emitted wavelength to a wavelength within the threshold variation or re-characterizing the laser.

Conveniently, the step of using the further values of applied currents comprises using one of the further look-up tables.

Conveniently, step g) comprises measuring, at predetermined intervals of time, an offset in the phase current as generated by a frequency-locker feedback-control circuit connected to the laser, to determine whether the offset is excessive and in danger of causing a mode hop; and sufficient to require re-characterisation of the laser which condition may trigger an alarm and, if the offset is excessive but not requiring re-characterisation, identifying and using the further values of applied currents stored when the laser was last characterised and if requiring re-characterisation, re-characterising the laser.

Conveniently, the step of determining whether any change in the values is sufficient to require re-characterisation of the laser comprises determining whether the phase current offset is greater than a predetermined value or represents more than a predetermined percentage change.

Conveniently, the frequency locker includes the graded refractive index lens.

Conveniently, the frequency locker includes a Fabry Perot etalon comprising mirrors embedded in slots in a waveguide.

Advantageously, the method comprises characterising a DS-DBR laser as if it were a collection of a plurality of conventional DBR lasers using an hysteresis property of such lasers.

Advantageously, where the laser is a tuneable laser containing one or more current tuneable reflection gratings and a Fabry-Perot cavity wherein the spectra of the grating and a nearby cavity mode overlap to produce a selectable lasing wavelength, the method comprises steps of: analysing a resulting hysteresis of longitudinal mode boundaries for meander and span to reject defective lasers; and identifying longitudinal mode middle lines for best operation to avoid mode hopping; and producing a look-up table of operating currents for desired optical frequencies therefrom.

According to a third aspect of the invention, there is provided a characterising apparatus for a tuneable multi-section semiconductor laser, the apparatus comprising current drive means for applying currents in step-wise increments to sections of the laser respectively; power measuring means for measuring power output by the laser to determine values of the applied currents corresponding to respective stable operating conditions for which the laser emits radiation at wavelengths remote from mode boundaries of the laser; wavelength measuring means for determining a respective wavelength of the emitted radiation; current measuring means for measuring variations in the applied currents required to cross a mode boundary such that the laser undergoes a mode jump to emit radiation at a wavelength significantly different from that under the respective stable operating condition; storage means for storing in a first look-up table respective values of applied currents for which the laser emits radiation at wavelengths remote from mode boundaries, the corresponding wavelengths of the radiation and the variations in applied currents required to cross adjacent mode boundaries for use of the laser under the characterising conditions and state of ageing of the laser and for storing further values of applied currents for each predetermined incremental change in wavelength respectively for use as the wavelength of radiation emitted changes by more than a predetermined threshold within the said mode boundaries.

Preferably, the power measuring means comprises a first photodiode connectable to the laser by optical waveguide means.

Conveniently, the wavelength measuring means comprises a feature extraction filter connectable to the laser by optical waveguide means and a second photodiode connectable to an output of the feature extraction filter by optical waveguide means.

Advantageously, the feature extraction filter comprises a dielectric multilayer coating on a transparent substrate located in the optical waveguide means between the laser and the second photodiode.

Conveniently, the wavelength measuring means further comprises a first Fabry Perot etalon filter or Fizeau filter, having a first Free Spectral Range (FSR), connectable to the laser by optical waveguide means and a third photodiode connectable to an output of the first Fabry Perot etalon filter or Fizeau filter by optical waveguide means.

Conveniently, the first FSR is substantially 5 GHz.

Advantageously, the first Fabry Perot etalon filter comprises first and second spaced apart, flat response, dielectric mirrors located in the optical waveguide means between the laser and the third photodiode.

Advantageously, the wavelength measuring means further comprises a second Fabry Perot etalon filter or Fizeau filter, having a second FSR different from the first FSR, connectable to the laser by optical waveguide means and a fourth photodiode connectable to an output of the second Fabry Perot etalon filter by optical waveguide means.

Conveniently, the second FSR is substantially 50 GHz.

Alternatively, the wavelength measuring means further comprises a second Fabry Perot etalon filter or Fizeau filter, having a second FSR and the first FSR and the second FSR are a same FSR between 50 GHz and 400 GHz and the first Fabry Perot etalon filter or Fizeau filter is out of phase by one quarter of the same FSR from the second Fabry Perot etalon filter or Fizeau filter so that the first and second filters are in quadrature.

Advantageously, the second Fabry Perot etalon filter comprises third and fourth spaced apart, flat response, dielectric mirrors located in the optical waveguide means between the laser and the fourth photodiode.

Advantageously, the wavelength measuring means further comprises a third Fabry Perot etalon filter, having a third FSR, connectable to the laser by optical waveguide means, and a fifth photodiode connectable to an output of the third Fabry Perot etalon filter, wherein the third FSR provides a local maximum in transmissivity at a same reference frequency as a local maximum in transmissivity provided by the first FSR.

Conveniently, at least some of the laser, feature extraction filter and first and second Fabry Perot etalon filters are interconnected by optical waveguide means to form a planar lightwave circuit on a substrate.

Conveniently, the optical waveguide means is a branched ridge optical waveguide.

Advantageously, the apparatus is arranged for characterising a DS-DBR laser as if it were a collection of a plurality of conventional DBR lasers using a hysteresis property of such devices.

Advantageously, the apparatus is arranged for characterising tuneable lasers containing one or more current tuneable reflection gratings and a Fabry-Perot cavity wherein a spectra of the one or more gratings and a mode of the nearby cavity overlap to produce a selectable lasing wavelength; and for analysing a resulting hysteresis of longitudinal mode boundaries for meander and span to detect defective lasers; and for identifying longitudinal mode middle lines for operation avoiding mode hopping to produce a look-up table of operating currents for desired optical frequencies.

According to a fourth aspect of the invention, there is provided a computer program comprising code means for performing all the steps of the method described above when the program is run on one or more computers.

A specific embodiment of the invention will now be described by way of example with reference to the accompanying drawings, in which:

FIG. 1a is a schematic diagram of a three-section semiconductor laser employing a known phase current frequency locker feedback control loop to stabilize output of the laser;

FIG. 1b is a schematic diagram of an apparatus for characterising a three-section semiconductor laser suitable for use in the present invention;

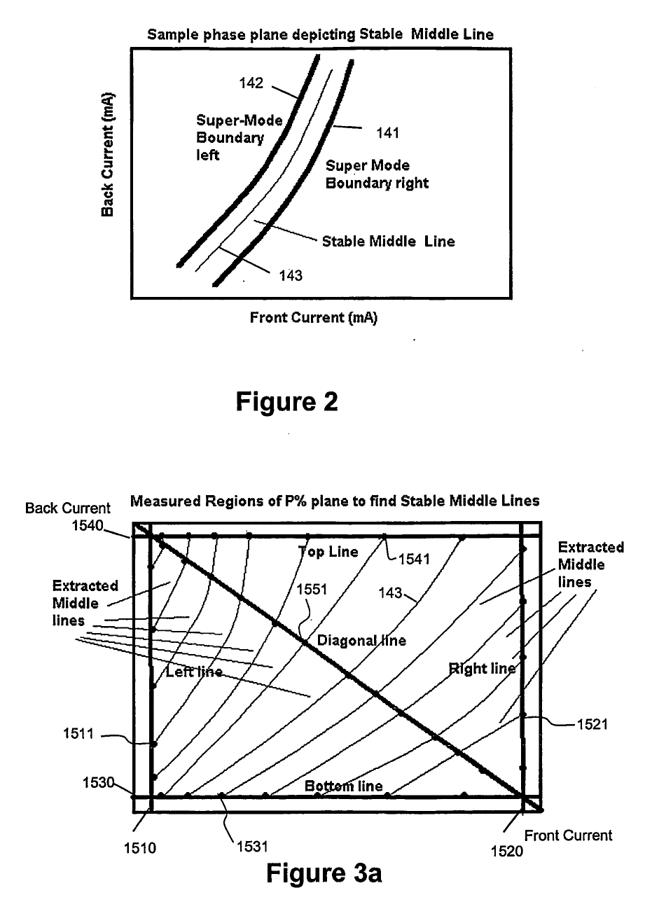

FIG. 2 shows a plot, useful in understanding the method of the invention, of current injected in a front section as abscissa and current injected in a back section as ordinates of a multi-section laser, having at least four sections, showing a stable middle line between two super-mode boundaries;

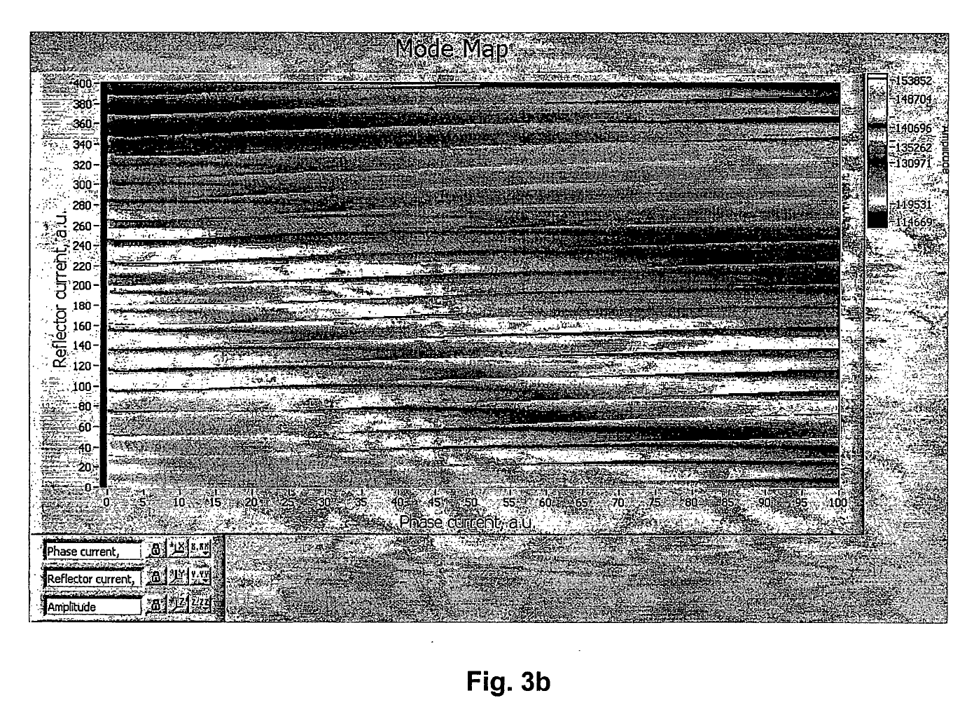

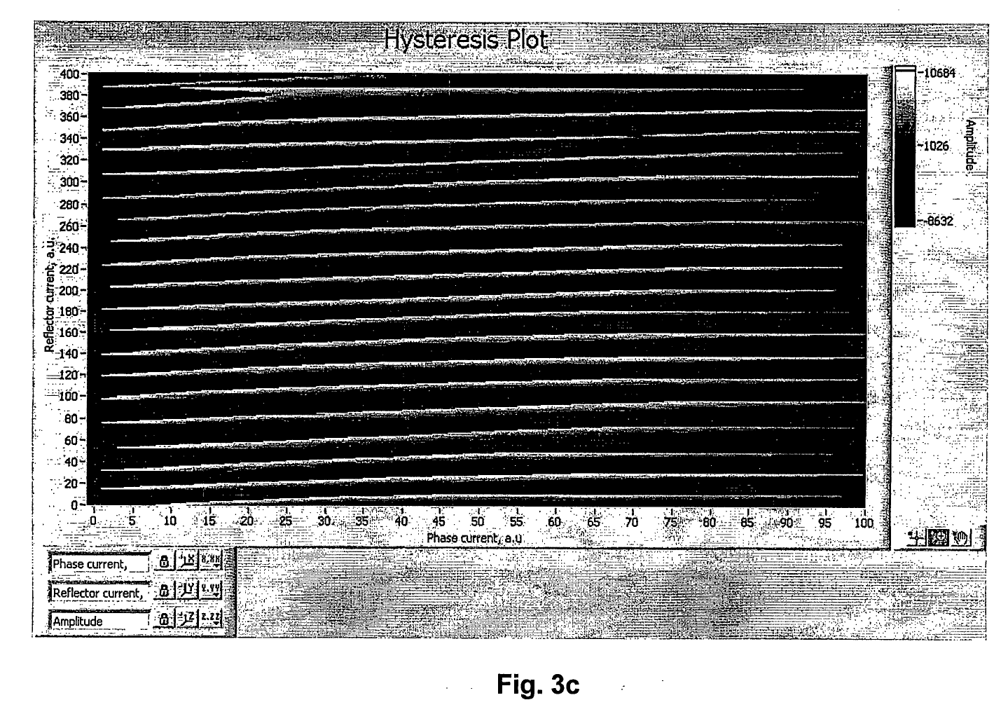

FIG. 3a shows a graph, useful in understanding the method of the invention, of current injected in a front section of the laser of FIG. 2 as abscissa versus current injected in a back section of the laser of FIG. 2 as ordinates, to determine the positions of stable middle lines such as that shown in FIG. 2;

FIG. 3b shows characterization data for a DBR laser (as a computer screen dump), used in an embodiment of the invention, of current injected in a phase section of the laser of FIGS. 1a and 1b as abscissa versus current injected in a reflector section of the laser of FIGS. 1a and 1b as ordinates, to determine the positions of stable middle lines such as that shown in FIG. 2;

FIG. 3c is similar to FIG. 3b, but shows mode boundaries displaced as a result of hysteresis.

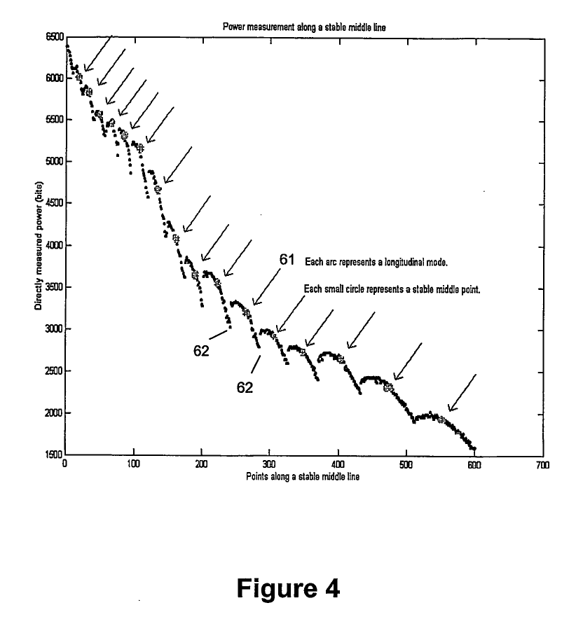

FIG. 4 shows a graph of power output of the laser of FIG. 2 along a stable middle line between mode boundaries such as that shown in FIG. 2, with distance along the middle line as abscissa and power emitted as ordinates;

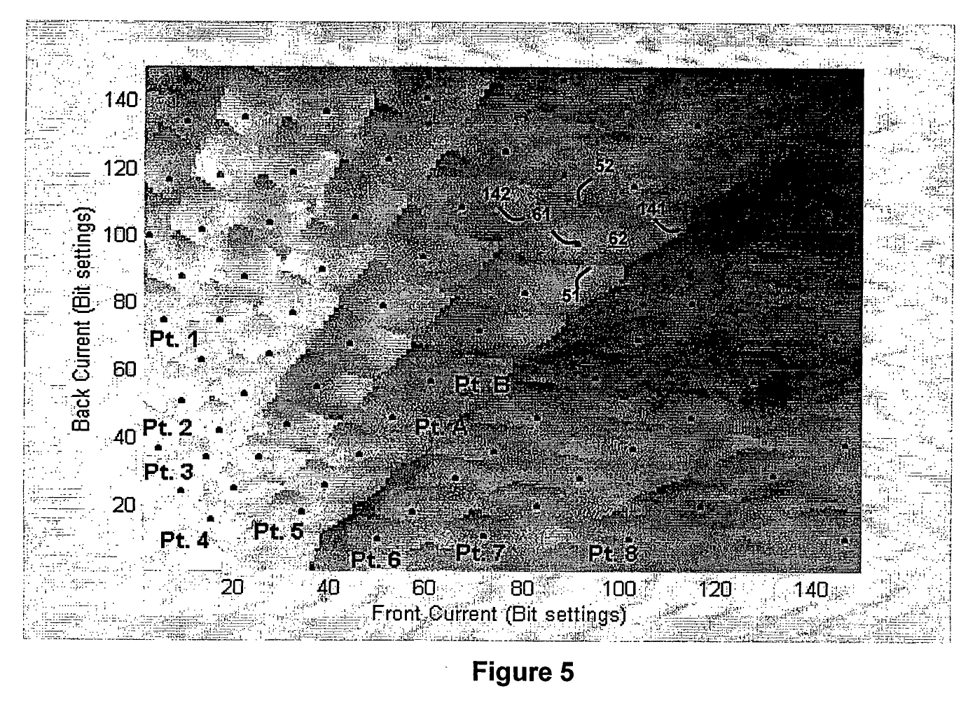

FIG. 5 shows a plot derived from FIG. 4, of stable operating positions between super-mode and longitudinal mode boundaries for a four-section laser;

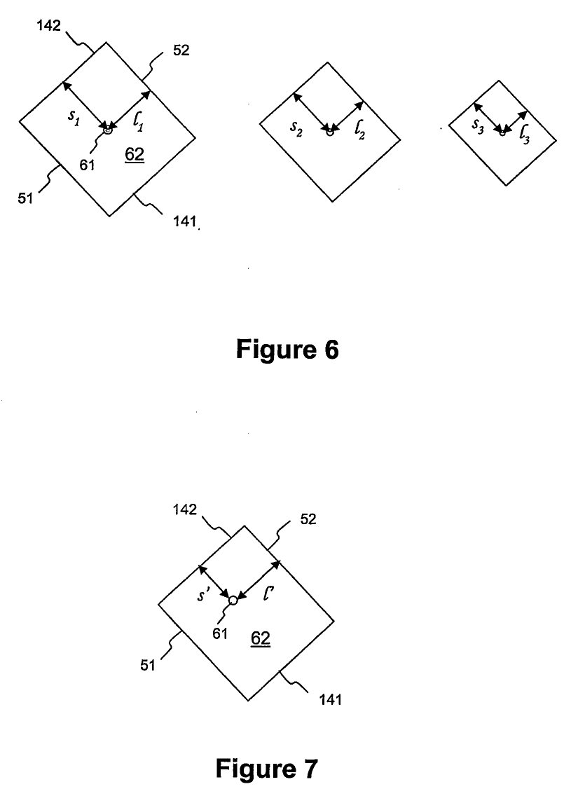

FIG. 6 shows a detail of FIG. 5, showing diagrammatically the location of stable operating points between super-mode and longitudinal mode boundaries;

FIG. 7 shows an operating point of FIG. 6 after ageing of the laser;

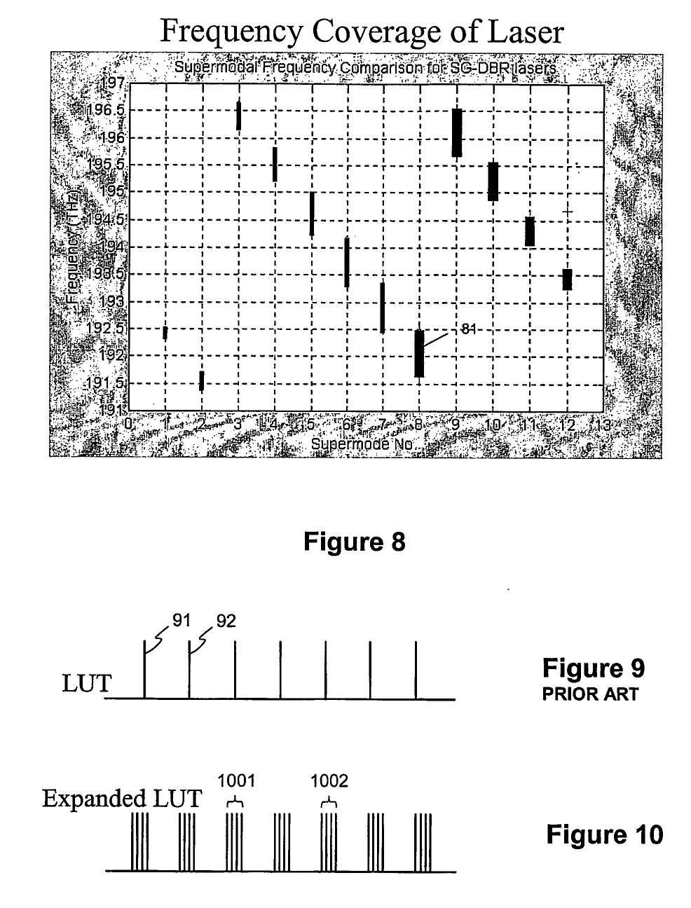

FIG. 8 shows a graph of frequencies as ordinates vs. supermode number as abscissa used in quality control of lasers;

FIG. 9 is a representation of a LUT according to the prior art, having entries at ITU frequencies;

FIG. 10 is a representation of a LUT according to an embodiment of the invention having entries at, and in the vicinity of, ITU frequencies;

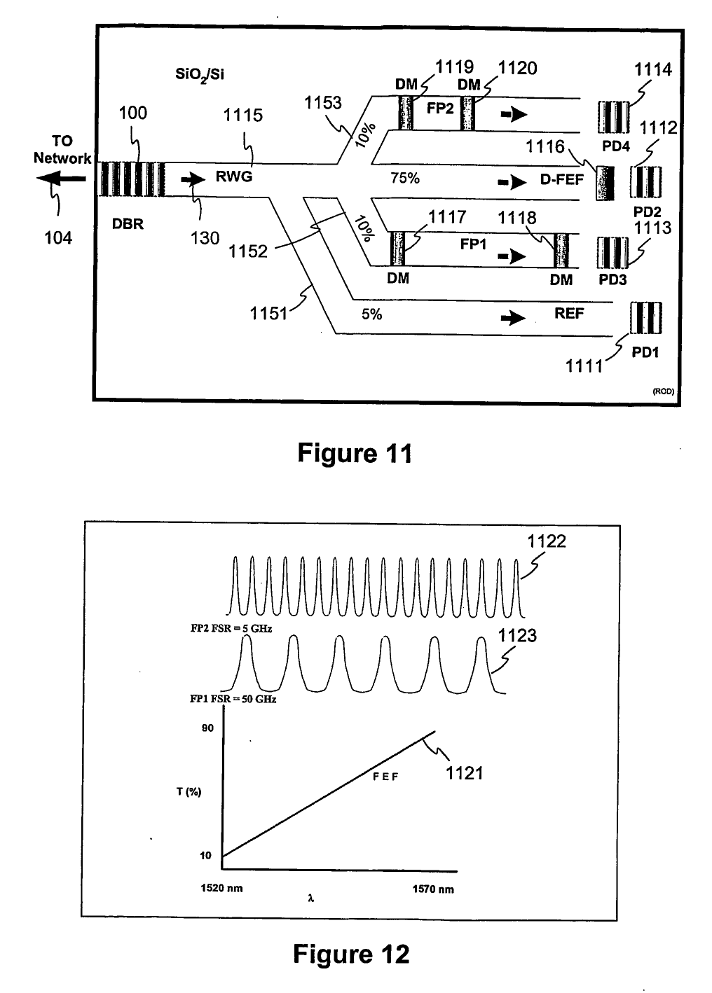

FIG. 11 is a schematic representation of a planar lightwave circuit embodiment of an apparatus for use with the invention;

FIG. 12 is a schematic representation of characteristics of filters used in the embodiment of FIG. 11, with wavelengths as abscissa and transmissivity as ordinates;

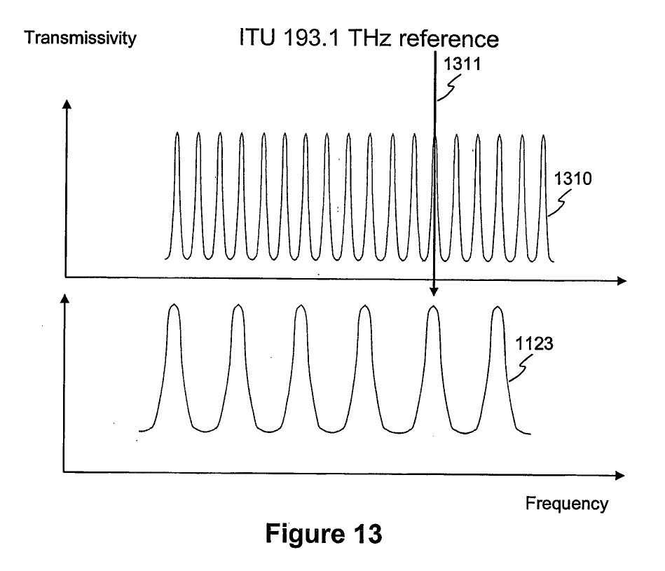

FIG. 13 is a schematic representation of characteristics of one of the filters of FIG. 12, and of an additional filter, each having a transmission peak in common at a frequency of interest;

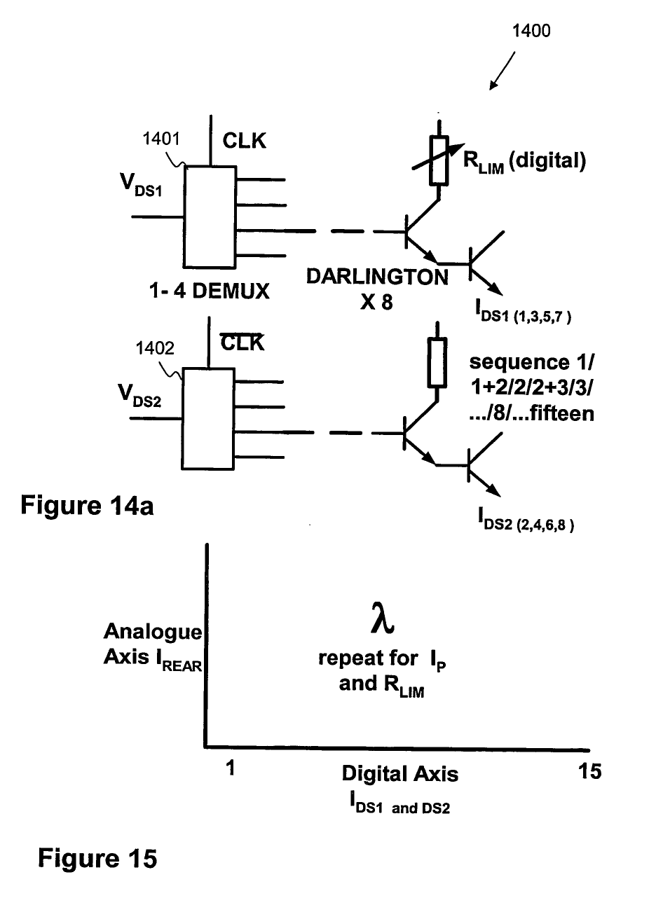

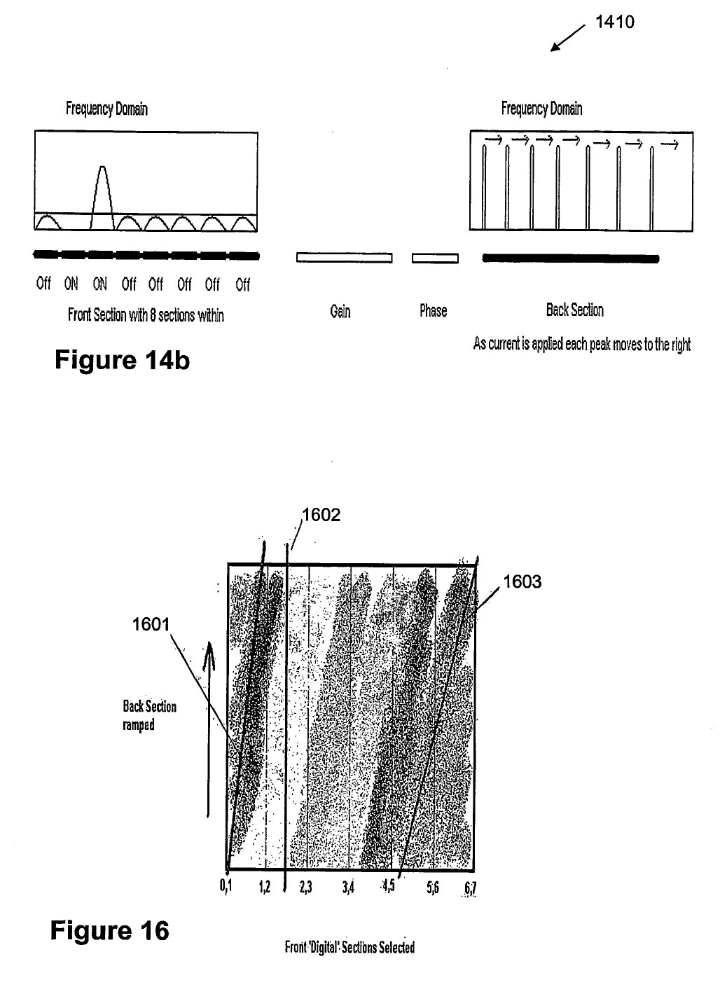

FIG. 14a shows a leap-frog drive circuit for a DS-DBR laser, suitable for use with the invention;

FIG. 14b is a schematic diagram of a DS-DBR laser, that can be characterized with the leap-frog circuit of FIG. 14b;

FIG. 15 is a plot of rear section current as ordinates and front digital section currents as abscissa for the DS-DBR laser of FIG. 14b; and

FIG. 16 is representation of a wavelength plane with digital front sections selected as abscissa and rear section current as ordinates for the DS-DBR laser of FIG. 14b, comprising seven regions of DBR laser-like operation.

In the figures, like reference numerals denote like parts.

A three-section laser is a relatively straightforward device and its control current plane may be visualized as a number of modes linked together. As part of the characterization disclosed in WO 03/038954 and IE S2001/0954, a stable position between mode boundaries is defined by a set of Cartesian coordinates. To select a stable channel the geometric centre between mode boundaries and a change in phase current required to transverse a mode are determined. In essence this is enough information to provide a non-invasive compensation technique. If a compensation algorithm is provided with the data detailed above, then by measuring a level of correction provided by the frequency locker 105 and relating this to an extent of the mode, it is possible to predict how close the laser is to mode hopping. A compensation algorithm is provided with a threshold (e.g. 50% of the way to next mode), which will trigger corrective action. The corrective action modifies the reflector current I_{R} so as to decrease the level of phase correction required i.e. moves an operating point away from a mode boundary back towards a geometric centre between mode boundaries.

The following reasonable assumptions are made with regard to the non-invasive compensation algorithm.
1. The ageing process causes the entire laser plane to drift; the shape of modes and mode relationships remains in constant proportion.
2. The frequency locker mechanism provides a way for the laser module's control CPU to determine a frequency error.
3. The laser will be operated as a pseudo fixed frequency laser that normally does not require fast switching. However the method may also be deployed in a wavelength switching environment with speeded up electronics, for example using an applications specific integrated circuit (ASIC).

As shown in FIG. 1a, a three-section laser 100 to be characterised has, arranged sequentially, a phase section 101, a gain section 102 and a reflector section 103 with respective current inputs I_{P}, I_{G} and I_{R}. When appropriate current inputs are applied laser light 104 is emitted from an end facet of the phase section 101. In use a frequency locker 105 is provided to adjust the phase current I_{P} to make fine adjustments of the frequency of the emitted laser radiation to maintain the laser emission 104 at a predetermined wavelength or frequency. The frequency locker 105 has an input 106 which taps the emitted laser radiation 104 to determine a frequency of the emitted laser radiation 104 and a first output 107 to vary the phase current I_{P} to maintain the predetermined frequency of the laser output 104. The frequency locker 105 has a second output 108 to provide an indication of the current offset currently being applied to the phase current I_{P} to maintain the predetermined output frequency of the laser.

As shown in FIG. 1b, in order to characterise the three-section laser 100, a feature extraction filter, 110, and a Fabry Perot (FP) etalon graded refractive index lens 120 are located in paths of a laser beam 130 emitted from an end facet of the reflector section 103 remote from the transmitted laser beam 104. Alternatively, the feature extraction filter, 110, and the Fabry Perot etalon graded refractive index lens 120 may be located in a tapped portion of the laser beam 104. The feature extraction filter 110 may be a long period grating, which is a grating in which corrugations or “lines” are sufficiently widely spaced that a transmission or reflection spectrum generated by the grating is sufficiently broad to give a monotonic variation with wavelength over, for example, the C-Band or L-Band, or both, for optical fibre networks. The grating may alternatively be incorporated in an optical fibre or a dielectric filter producing a similar monotonic transmission spectrum. The graded refractive index (GRIN) lens 120 may be used as part of the frequency locker 105 as well as a second, precision filter. The GRIN lens is designed to behave as a collimator and Fabry Perot etalon simultaneously to act as a fine resolution optical filter during characterization, rather than using a more cumbersome wavelength meter; but providing an input to the frequency locker when the laser is deployed, for example in an optical WDM network. Alternatively the locker may be a Fabry Perot etalon embedded in a planar light-wave circuit, PLC, or a sequence of such filters that provides transmission spectra suitable for coarse and fine optical frequency identification. Each filter may be created by fabricating a pair of slots along the waveguides of the PLC that are then modified as mirrors thereby providing an optical cavity of known length and Free Spectral Range in a variation of that disclosed in WO 01/28052.

The invention may be applied to, for example, a known three-section DBR laser, a four-section InGaAsP sampled grating distributed Bragg reflector (SG-DBR) laser or a gain coupled sampled grating reflector (GCSR) laser. In the latter case one grating section is instead a middle section, the coupler. Alternatively, a superstructure SG-DBR (SSG-DBR) laser may be used. The invention is also applicable to, for example, a five-section laser, the fifth section being a semiconductor optical amplifier to provide a higher power output. The invention is also applicable to a multi-section laser wherein, for example, the front grating section is divided into eight or more further sub-sections with individual input currents, the so-called digital supermode DBR (DS-DBR) type. Referring to FIG. 14a, a leap frog driver circuit 1400, so-called herein, may be used for such a DS-DBR laser 1410 shown diagrammatically in FIG. 14b. The leap-frog circuit 1400 limits a front current I_{F} to each front sub-section of the multi-electrode DS-DBR laser 1410 using a known fast digital potentiometer component R_{LIM}. At selected bias current levels I_{F1} and I_{F2}, a first two sub-sections of the laser are driven to reflect a part of the spectrum and the rear current I_{REAR} is scanned from typically 0 to 60 mA. Next the front currents I_{F} are incremented through about 10 mA while the process of scanning the rear current I_{REAR} is repeated at each setting. The multiplex circuit 1401, 1402 is invoked to drive a next pair of front sub-sections and the above process characterisation stages are repeated for seven sub-regions. In this manner a full wavelength plane, as shown in FIGS. 15 and 16, is obtained including features of each sub-region of the DS-DBR operated as if it were a digitally selected DBR laser. Each of the seven DBR operating regions shown in FIG. 16 covers a different band of the ITU frequency plan and is analysed by the method disclosed in WO 01/28052 and GB 0306724.6 to identify stable middle lines and subsequently store ITU operating currents in a look-up table. A first line 1601 is a non-ideal line that stays within a supermode and uses a same two front current sections but varying currents within the sections. A second line 1062 is an ideal digital selection for a single supermode. A third line 1603 is a non-ideal line that remains within a supermode but crosses into two sets of front current sections with front currents all changing. That is, the DS-DBR laser digitally selects supermodes. The use of the leap-frog driver 1400 greatly simplifies the characterisation of these lasers which have eight inputs to one reflector section. The driver circuit drives the eight front sections of a DS-DBR laser two at a time in leap-frog sequence to cover all operating conditions and access all of the C-band. An electro-absorption modulator (EAM) may be monolithically integrated, or hybridised with the laser to provide data modulation of the laser output.

An alternative to the leap-frog driver is to arrange a set of eight current driver circuits where each connects to one of the eight sub-sections of the front reflector and that are sequenced, according to a sequence engine available from PXIT, Ireland, to produce the same result albeit in a less compact fashion.

The laser and characterising apparatus may be deployed in a non-hybridised form, as depicted in FIGS. 1a and 1b, wherein the laser 100, beam splitters to divide the laser beam (not shown), feature extraction filter 110, FP etalon 120, wavemeter, if used, current driver circuits, not shown, microprocessor, not shown and frequency locker feedback circuits are separate bulk components that comprise the apparatus, or may be in a hybridised form.

Rather than being connected to an inline, hybridised Fabry Perot etalon, the output of the long period grating, or feature extraction filter, may be connected to an external frequency locker, as shown in FIG. 1 a for a three-section DBR laser.

In an alternative application of the invention, the laser, waveguide and photodiodes may form a monolithic device in a semiconductor alloy, rather than being combined in a hybrid optical device. By a hybrid optical device it is to be understood a hybrid of active and passive devices or a hybrid of devices in different materials e.g. glass and semiconductor.

Referring to FIG. 1b, the known long period grating, or feature extraction filter 110, has a transmission characteristic in which the percentage of power transmitted to a second photodiode PD2 is substantially linearly inversely proportional to the wavelength of incident light. For example, power transmitted to the second photodiode PD2 as a percentage of power in a reference beam not passing through the filter transmitted to a first photodiode PD1 varying from 10% to 90% in the range 1520 nm to 1560 nm in a substantially linear manner is useful for C-band operation. Variations of 5% to 95% have been achieved. This range is crucial to precision wavelength identification and may also be achieved using a multi-layer dielectric filter.

Instead of the long period grating, or feature extraction filter, filters of other types may be used. For example, a photonic band-gap crystal, with a slowly changing spectral response, may be utilized. Other possible filters are an optical fibre or waveguide with an embedded diffraction grating or with an embedded multilayer dielectric mirror.

Although, as described, the characterising functions are carried out from light emitted from a “rear” face of the laser, all these characterising functions can be carried out from the “front” power output face. This is particularly so in the case of a gain coupled sampled grating reflector (GCSR) laser, for example.

In order to characterise the laser it is necessary to find stable positions, remote from mode boundaries, where the laser will operate at a stable frequency without mode-hopping. Such stable points may be found on stable middle lines 143 halfway between super-mode boundaries 141,142, as shown in FIG. 2 or directly from the phase-current I_{P} versus reflector-current I_{R} plane in the case of a DBR laser where the points are mid-way between longitudinal mode boundaries.

As disclosed in WO 01/28052 and shown in FIG. 3a, the position of these stable lines in a four-section laser can be obtained by sampling. Measurements are made in five stages along five or more lines of measurement as follows. The front current is held at a first constant value 1510 and the back, or rear, current varied to determine stable points 1511 corresponding to intersections of stable middle lines with this first line of measurement. The front current is held constant at a second value 1520 and the back current varied along a second line of measurement to determine stable points 1521 representing points of intersections of the stable middle line with the second line of measurement. The back current is held constant at a third constant value 1530 and the front current is varied along a third line of measurement to determine stable points 1531 representing points of intersection of the stable middle lines with the third line of measurement. The back current is held constant at a fourth value 1540 and the front current is varied along a fourth line of measurement to determine stable points 1541 represented by an intersection of the stable middle line with the fourth line of measurement. The front current is increased from the first constant value 1510 to the second constant value 1520 while the back current is decreased from the fourth constant value 1540 to the third constant value 1530 along a fifth line of measurement to find points of intersection 1551 of the stable middle lines with the fifth line of measurement. Conveniently, the currents are varied by a fast programmed waveform with a frequency in the region of 100 kHz. With faster electronics it is anticipated that Megahertz frequencies may be used. Stable middle lines 143 can then be plotted by joining corresponding points of intersection on the respective lines of measurement as shown in FIG. 3a. To refine plotting of the stable middle lines, additional diagonal lines of measurement, parallel to the diagonal line of measurement shown in FIG. 3a, may be used. In an embodiment of the invention up to 100 diagonal lines of measurement may be used with pre-programmed waveforms rapidly to produce a mode map, as shown in FIG. 5, for visual inspection. In the case of GCSR lasers, in the fifth step, coupler and back currents respectively may be varied between different constants, to accommodate a different orientation of the super-modes in GCSR lasers.

In the case of a three section DBR laser 100 the rear reflector current I_{R} may be held constant at successive incremental values while for each such value the phase current I_{P} is swept rapidly from zero to maximum and back to zero. Conveniently, in this case I_{R} and I_{P} maybe interchanged for this step or the increments in I_{R} and I_{P} may be unequal in a fashion that results in the mode-map (see FIG. 3b) appearing to have almost equally spaced mode boundaries. This process causes the rising and falling currents to generate slightly displaced mode boundaries as a result of hysteresis in the laser. The boundaries that thereby depict hysteresis, as shown in FIG. 3c, may be used, as described hereinafter, to locate stable middle lines in a similar fashion to that described above.

In this manner, for a four-section laser, it is possible to plot a number of stable middle lines between super mode boundaries such as that shown in FIG. 2. The stable operational points are then sought on these stable middle lines 143 midway between longitudinal mode boundaries 51,52, see FIGS. 5 and 6, which transversely cross the stable middle lines 143 and the super-mode boundaries 141,142.

Moving along such a middle line and measuring the direct power for each point results in a plot such as that shown in FIG. 4. The local minima 62 in the power output correspond with the longitudinal mode boundaries 51,52. The requirement then is to find the stable points 61 which are taken to be midway between two local minima 62 in the power output. To determine the local minima 62 a moving window may be used which has a fixed number of measurement points, for example, initially 10 points. The point, within the 10 points of the window, having a minimum power value is recorded and then the window moved by one point to determine the new point having a minimum power. A local minimum 62 is that point which returns a minimum value for each of 10 successive movements of the window. However, as can be seen from FIG. 4, further along the middle line a wider window is required to encompass the wider arcs, up to 150 measurement points, for example.

Having established the local minima, the positions of the stable middle points 61 can be located as shown in FIG. 4, being midway between local minima. As the position of the stable middle points are established they may be stored in a look-up table.

In this manner stable points 61 located between super-mode boundaries 141,142 and between longitudinal mode boundaries 51,52 may be identified as shown in FIG. 5.

Power planes for phase current I_{P} versus rear reflector grating current I_{R} are gathered in forward and reverse directions, that is with currents incrementing and decrementing respectively. Boundary-detection is performed by computer analysis in both forward and reverse directions, based on longitudinal mode power jumps. The forward and reverse boundaries are different due to hysteresis that is accounted for by a rear reflector spectrum and a cavity mode spectrum overlapping and feeding back photons at different rates when the direction changes between incrementing and decrementing currents. The planes derived from the forward direction and reverse direction are superimposed, as shown in FIGS. 3b and 3c, to identify hysteresis regions of operation, in which the laser is un-stable for mode-hopping and has low longitudinal or cavity side-mode suppression. Detection of excessive meander or span for the hysteresis regions allows defective laser chips to be screened out and rejected by computer analysis of this topology. The middle lines for the modes are identified as disclosed in WO 01/28052 and are those between the reverse n^{th} mode boundary and the forward (n−1)^{th} mode boundary for any region n. The middle lines will contain the ITU operating points for storage in a look-up table. These are identified by measuring the frequencies at start and end of lines, using a fast wavelength meter as disclosed in GB 0306724.6 for example, and interpolating to the required ITU channel.

In general, operational conditions for operating at frequencies between the stable middle point frequencies are determined and stored in the look-up table. The required values of phase current injected into a phase section of a laser with greater than three sections are determined by holding the back and front currents constant successively at a first stable point and incrementing the phase current until a frequency of laser emission corresponding to a next stable point is reached and calculating what increments of phase current are required to step from the first stable point to the second stable point in desired frequency increments.

For the DBR laser 100 the phase current I_{P} may be incremented along the stable middle lines so as to produce optical frequencies that are equally spaced, 1 GHz or 200 MHz apart, for example. This process can be followed to generate a set of look-up tables that produce optical output from the laser firstly at ITU frequencies and then other grids of frequencies that produce ITU channels displaced by intervals of plus or minus 100 MHz, for example. A set of perhaps thirty LUTs may thereby be generated and stored for later use as the laser ages.

Thus a basic 20 channel ITU Grid lookup table disclosed in WO 03/038954 and IE S2001/0954 is extended to include mode extent and phase control data for each channel. The reflector correction currents may, for example, be provided by the use of multiple look up tables spaced 200 MHz apart. Each look-up table may contain:

Mode Start current and Mode End current as integers

Phase Control as integer

Array of 20 reflector current values as integers

Array of 20 phase current values as integers

Where 30 tables are required the control system requires storage of 3K bytes of ROM. As all the difficult computation is carried out at initial characterization, an embedded CPU has very little calculation to carry out. Because the whole mode map ages in a uniform manner, the CPU need only deal with one channel requiring a read of 10 bytes for the channel selection currents, mode extent and phase control values. The CPU measures the level of correction provided by the frequency locker and relates this to the mode extent to predict how close the laser is to mode hoping. When a threshold (e.g. 50% of the way to next mode) is exceeded, corrective action is taken; the processor reads a new set of values from its ROM look-up table and changes from a present reflector current to a new reflector current. As ageing is a very slow process, the compensation algorithm can operate at an extremely low priority and can take as long as necessary to carry out its task. As the computations can be done using integer arithmetic, the overhead on the embedded processor is very small.

The ageing process tends to cause the frequency of the emitted laser radiation to diminish so that when monitoring of the frequency locker correction to the phase current indicates that the I_{P} offset exceeds a first threshold that produces minus 100 MHz output at original characterization, then the next LUT is invoked thereby resetting all channels at the ITU grid but with zero offset and with all channels located at the centre of the mode regions as at the start of laser life. With even further ageing the next nearest LUT is invoked and so on. In this way non-invasive monitoring and correction for ageing is achieved. If the offset exceeds a second threshold, higher than the first threshold, an alarm may be triggered indicating that the laser requires recharacterisation. A corresponding method may be applied to lasers with a greater number of sections.

Similar principles can be applied in other uses associated with these lasers. It is desirable that the optical power is equalised by adjusting the LUT gain current values as described in WO 01/28052. When the gain current is lowered, for example where a particular channel outputs 10 mW but all channels are required to be at 5 mW, the effect is slightly to increase the frequency so the multiplicity of stored LUTs may be invoked to re-adjust the frequency back to the ITU grid.

Furthermore, the same principles can be useful in wavelength switching applications, for example wavelength labelling of IP packets for all-optical data routing. When switching to a channel of higher drive currents the laser is heated causing the optical frequency to overshoot the target channel for a microsecond or thereabouts. An adjacent LUT may be temporarily invoked that produces the correct ITU channel until the ageing routine above seeks the correct LUT after frequency settling. Alternatively, the driver circuits may be left under control of the “wrong” LUT while the frequency locker circuit adjusts the phase current. A combination of the above interventions may be deployed to maximum benefit.

Referring to FIG. 6, as disclosed in WO 03/038954 and S2001/0954 there is provided a method to produce stability factors, shown by double arrow-headed lines s,l, in relation to each of these stable points 61 respectively that indicate whether mode-hopping is likely or becoming more likely with ageing or other degradation. These stability factors s,l measure a distance of the stable operating points 61 from the mode boundaries 52,142 that characterize the laser behaviour when the tuning currents are incremented. The nearer the operating point 61 is to a mode boundary 52,142 the more likely that a mode hop is imminent thereby de-stabilizing the communication network.

A four-section laser has two coarse-tuning electric currents, I_{F} and I_{B} (front and back grating sections for SGDBR lasers) or I_{G} and I_{C} (grating and coupler sections for GCSR lasers) and the laser power and wavelength are first characterized as a function of these two inputs as described above. In the three-section DBR case the characterization proceeds directly to the I_{P}-I_{R} plane. This produces planes of data that are divided by mode boundaries 51,52,141,142 that must be avoided to prevent mode-hopping by the laser. The mode regions 62 between mode boundaries generated by the method disclosed in WO 01/28052, and outlined above, have a distribution of sizes depicted schematically in FIG. 6 with stable operating points 61 of the laser are at the centre of each region, having respective stability factors s₁, l₁; s₂,l₂, and s₃, l₃.

Stable middle points 61 inside the mode regions 62 have a range of implied “stability” as indicated by values s and l, that is the distances of the stable points from the neighbouring super-mode boundaries 142 and longitudinal mode boundaries 52 respectively, or by their values when normalised to an average of the highest 10% of values giving S and L, each between 1.0 and 0.3 typically. Thus, a channel with L,S=0.5,0.4 for example is less inherently “stable” than one with L,S=0.9,0.8. Alternatively, some other suitable reference values of l and s representing a reticle of a reference size of mode region 62 may be used to normalise the values.

An extended LUT includes L,S for use as a quality control parameter for selection of excellent lasers and also to facilitate statistical analysis of a batch as well as for monitoring ageing of the lasers.

An invasive monitoring method comprises a curtailed version of the look-up table generation procedure described above to check s and l values to ascertain whether ageing is causing the original “stability” to deteriorate.

In a first embodiment of the non-invasive method of the invention, monitoring comprises identifying at what point the offset to the phase current produced by the frequency locker feedback 105, see FIGS. 1a and 1b, exceeds a pre-determined “safe” value; at which stage a new LUT is activated using the multiplicity of LUTs generated at initial characterization.

In the invasive method of the prior art, initial values for the stable points are determined during the processing stage illustrated in FIG. 4. That is, having determined a position mid-way between two local minima, the distance l from the mid-way position, representing a stable point, and a local minima, representing a longitudinal mode boundary, is known.

The initial s values are determined, after the stable middle points are identified, by measuring a distance from a supermode boundary by biasing the front and back currents to drive the laser at the stable point and incrementing the front and back currents sufficiently to cross a supermode boundary. This is detected by a large change in wavelength and/or power emitted by the laser. Electronically this process may be implemented by subjecting the laser to a fast programmed current waveform using digital to analogue converter circuits. For non-invasive monitoring the detection is derived from the off-set to the phase current generated by the frequency locker control.

The original LUT has the original or last-measured s and l values stored for comparison with the new values s′,l′ shown in FIG. 7.

If after a period these values have changed significantly preventative action can be taken, for example, the laser may be re-characterised or replaced. A threshold change indicating that the laser has aged or otherwise deteriorated may be determined from a change in value exceeding a predetermined permitted change or a percentage change exceeding a predetermined permitted percentage change.

The invasive monitoring method is a diminutive version of the full look-up table characterisation. Referring to FIG. 8, in which each of the frequency bars 81 indicates a frequency range emitted by a four-section laser for a respective supermode number, after finding stable operating points for a laser chip away from mode boundaries, the laser chip is tested to ensure that all frequencies in a range of interest may be generated, as in the case shown in FIG. 8. That is, taken together, all the frequency bars 81 cover the required frequency range, without any substantial frequency gaps. If all the frequencies cannot be generated, the chip fails the quality control monitoring test and is rejected, without proceeding to the generation of a look-up table for the laser. However, for chips which pass the quality control test, the look-up table is generated after the laser is packaged. Thus the use of a screen display of the frequency coverage of a laser on a chip, corresponding to FIG. 8, provides an extremely fast quality test for laser chips.

It is found in the prior art that invasively monitoring the stability factors takes about 1 minute per laser, with line terminal equipment per telecommunications optical fibre comprising 160+40 lasers, a full check may be carried out in 200 minutes compared with 36 or more hours downtime required with alternative known schemes.

Alternatively, a single stable point may be located within a few milliseconds. It is anticipated that this may be achieved even faster with improved microcircuits.

The invasive method comprises the use of a filter as described in WO 01/28052, along with current input and power and wavelength output data acquisition circuits (DAQs). While the LUT is being generated the stability factors are also gathered and stored. These can be periodically checked using the stable middle lines 143, shown in FIG. 2, for the laser by applying programmed electronic waveforms.

The non-invasive method of the invention comprises sensing the correction to the phase current as generated by the frequency locker control circuit and determining whether this offset is sufficient to endanger a state of mode hopping; in such a case selecting a modified LUT from the data gathered and stored at initial characterization.

A further embodiment of the invention for non-invasive stability and recalibration requires storing only one look-up table. In this embodiment the laser is operated together with a wavelength or frequency locker 105. The wavelength locker may modify the phase current at any given moment to achieve (or return to) lasing at a desired wavelength. Such a wavelength-locking loop operates continuously; however, corrections for mirror currents (one current in the case of a 3-section device, or two currents in the case of a 4-section device) will be taken from time to time—when a threshold is reached.

Generally, there will be a trade-off between how much data can be stored in ROM and how many points should be created in the LUT: obviously it is necessary to have sufficient information in the LUT within realistic limits on memory requirements. In this further embodiment the LUT is “expanded” (with 300 MHz spacing) only around the predetermined ITU channels (say within ±2 GHz around the ITU channel) and at frequencies distant from the ITU channels the LUT is not expanded. Since frequency drift>1 GHz is expected to be intolerable, it is preferable not to waste memory on storing excessive information on frequencies that will never be used (i.e. in gaps between ITU channels). This approach—in which only regions within ±2 GHz around the ITU channels are sampled—does not require much more memory than the method of the prior art.

That is, this further embodiment provides an alternative non-invasive recalibration by using an LUT expanded only in the vicinity of the predetermined ITU channel frequencies but not remote from these frequencies. The expanded parts of the LUT are generated after a standard characterization procedure has been run and a LUT has been generated at ITU channel frequencies, e.g. 91, 92 shown in FIG. 9. The LUT is then expanded, see FIG. 10, in the vicinity of the ITU channel frequencies 91, 92. For each of the ITU channels, information is collected within a frequency range e.g. 1001, 1002 within ±2 GHz around the ITU channel. This is the only “expanded” characterization that needs to be performed on the laser.

It is possible to emulate the laser ageing process by changing the temperature and measuring the predicted LUT that can be expected after a period of time. This predicted LUT may be stored for later use when frequency correction by the wavelength locker has exceeded a pre-determined threshold that signals a danger of mode-hopping.

A non-invasive control environment that permits a laser to be characterized as described in the foregoing description and later monitored for ageing is depicted schematically, by way of example, in FIG. 11 wherein optical elements are miniaturized in a planar lightwave circuit (PLC) on a SiO₂/Si substrate, hybridized with a DBR laser and four photodiodes. The PLC includes a flip chip mounted DBR laser 100 and four photodiodes 1111, 1112, 1113, 1114. The laser has a first output 104 from a first end facet to a telecommunications network and a second monitoring output 130 to the four photodiodes from an end facet opposed to the first end facet. The four photodiodes are connected to the DBR laser by a branched ridge waveguide 1115. The first photodiode 1111 is connected to receive a 5% reference beam, along a first branch 1151 of the branched ridge waveguide 1115, from the DBR laser 100. The second photodiode 1112 is connected to receive a 75% beam, through the branched ridge waveguide 1115, after transmission through a dielectric feature extraction filter 1116. The third photodiode 1113 is connected to receive a 10% beam, through a second branch 1152 of the branched ridge waveguide 1115, after transmission through a ˜5 GHz first Fabry-Perot etalon FP1 comprising first and second spaced apart dielectric mirrors, 1117, 1118, slotted into the second branch 1152 of the waveguide. A fourth photodiode 1114 is connected to receive a 10% beam, through a third branch 1153 of the branched ridge waveguide 1115 after transmission through a second Fabry-Perot etalon FP2, with an FSR of ˜50 GHz, comprising third and fourth spaced apart dielectric mirrors 1119, 1120 in the third branch 1153 of the waveguide.

The course feature extraction filter 1116 comprises a dielectric multilayer coating on a glass substrate with monotonic frequency response across the C-band and placed in an etched slot in the ridge waveguide 1115; while the medium and fine frequency identification filters FP1 and FP2 are Fabry Perot (FP) etalon filters, comprising, for example, 95% dielectric mirrors with flat response and inserted in slots, less than 100 micron thick, in the second and third branches 1152, 1153 of the PLC waveguide 1115. Typically, as described, the FP etalon filters FP1 and FP2 have 5 GHz and 50 GHz free spectral range respectively. Alternatively the two FP or Fizeau filters may beneficially have equal FSRs of typically 50 GHz to 400 GHz, but out of phase relative to each another by one quarter of the FSR, i.e. in quadrature as disclosed in GB 0306724.6. This has the beneficial effect that the capture range for an external, frequency wave-locker, which as conventionally deployed with lasers is typically limited to ±20% of the said locker FSR, is extended to full range and is no longer limited by the locker itself.

The transmission characteristics 1121, 1122, 1123 of the feature extraction filter 1116 and the FP etalon filters FP1 and FP2 are shown schematically in FIG. 12, respectively. The FP etalon filters, being less than 20 mm long, are well suited to silica waveguide based hybrid lightwave circuits that have low optical loss at telecommunications wavelengths.

The waveguide 1115 may be tapered adjacent to the laser 100 to improve optical coupling efficiency. The DBR laser may be conveniently connected to the network by the inclusion of a V-groove on the PLC, not shown, that facilitates positioning of an optical fibre transporting the main laser beam 104. In a variation of the apparatus the tuneable laser may be positioned externally to the PLC, as a remote laser, and the V-groove may be extended to the waveguide to couple light from the optical fibre into the apparatus.

A third FP etalon FP3, not shown, may be included by inclusion of a fourth tap or branch waveguide, not shown, opposite first branch 1151, leading to a fifth photodiode PD5, not shown. By careful design of the FSR 1310, see FIG. 13, of this third fine-tuning FP etalon FP3 it has been found that the combination of FP1 and FP3 can have a common transmission peak 1311 at the ITU reference frequency 193.1 THz or wavelength 1552.52 nm. This is useful because ITU Standard G692 utilises this frequency to anchor a grid of frequencies used for optical communications. Temperature stabilization to 0.01 degrees Celsius, by known means using a Peltier cooler, can provide better than 50 MHz frequency stability. By this means when PD5 and PD3, corresponding to the two fine tuning FP etalons, produce maximum outputs simultaneously the remote or on-board laser is known to be emitting at the ITU reference channel. This provides a valuable means to calibrate lasers, WDM equipment and networks.

1. A method of characterising a tuneable multi-section semiconductor laser such that a wavelength of the laser changed by more than a threshold variation may be accommodated, the method comprising the steps of:
a) applying currents (I_{P}, I_{G}, I_{R}) in step-wise increments to sections of the laser respectively;
b) measuring power output by the laser to determine values of the applied currents corresponding to respective stable operating conditions for which the laser emits radiation at wavelengths remote from mode boundaries of the laser;
c) determining the respective wavelength of the emitted radiation;
d) measuring variations in the applied currents required to cross a mode boundary such that the laser undergoes a mode jump to emit radiation at a wavelength significantly different from that under the respective stable operating condition;
e) storing in a first look-up table respective values of applied currents (I_{P}, I_{G}, I_{R}) for which the laser emits radiation at wavelengths remote from mode boundaries, the corresponding wavelengths of the radiation and the variations in applied currents required to cross adjacent mode boundaries for use of the laser under the characterising conditions and state of ageing of the laser;
f) varying the applied currents, to cause predetermined incremental changes in wavelength of the emitted radiation, within the said mode boundaries, and storing further values of applied currents in a first of further look-up tables for the predetermined incremental change in wavelength for use of the first of further look up tables in place of the first look-up table as the wavelength of radiation emitted with currently used applied currents changes by more than a predetermined threshold change; and
g) repeating step f) a further plurality of times, to store further look-up tables other than the first further look-up table for use in place of the first further look-up table or of one of said other further look-up tables as the wavelength of radiation emitted with a currently used look-up table changes by more than a further predetermined threshold change.

2. A method as claimed in claim 1, wherein the step of storing further values of applied currents comprises storing further values corresponding to frequencies only in a predetermined range in the vicinity of predetermined required frequencies of emission of the laser.

3. A method as claimed in claim 2, wherein the predetermined range is ±10 GHz.

4. A method as claimed in claim 3, wherein the predetermined range is ±2 GHz.

5. A method as claimed in claim 1, wherein step a) comprises applying currents in step-wise increments using a programmed waveform.

6. A method as claimed in claim 5, wherein the programmed waveform has a frequency of substantially 100 kHz.

7. A method as claimed in claim 5, wherein the programmed waveform has a frequency of substantially 1 MHz.

8. A method as claimed in claim 1, wherein step d) of measuring the variations comprises deriving the variations by determining distances (l, s) in an applied current plane of a point corresponding to the stable operating condition from adjacent longitudinal mode boundaries and, for a laser having four or more sections, from adjacent super-mode boundaries.

9. A method as claimed in claim 1, wherein step c) includes the steps of:
c1) providing an optical filter, or feature extraction filter, for transmitting a proportion of power of an incident light beam emitted by the laser, the proportion being dependant on the wavelength of the incident light beam; and
c2) measuring the proportion of power transmitted by the filter to determine the wavelength of the emitted radiation.

10. A method as claimed in claim 9, wherein the optical filter comprises multiple passive optical filters.

11. A method as claimed in claim 9, wherein the optical filter comprises a graded refractive index lens for use as a precision optical filter.

12. A method as claimed in claim 1, wherein, for a multi-section semiconductor laser having a gain section, a phase section and at least one tuning section, step a) includes the steps of:
a1) applying constant currents to the gain and phase sections such that the laser emits laser radiation; and
a2) applying at least one tuning current in step-wise increments to the at least one tuning section respectively; and
step e) includes storing in the first look-up table the values of the at least one tuning current for which the laser emits radiation at wavelengths remote from mode boundaries.

13. A method as claimed in claim 12, wherein, for a three-section laser, the at least one tuning section comprises a reflector section.

14. A method as claimed in claim 12, wherein, for a three-section laser, step a) comprises varying a reflector current (I_{R}) to determine stable points midway between longitudinal mode boundaries.

15. A method as claimed in claim 12, wherein, for a laser having more than three sections, the at least one tuning section comprises a front section having an applied front current and a back section having an applied back current and step a) comprises holding the front current at a first front constant and varying the back current, holding the front current at a second front constant and varying the back current, holding the back current at a first back constant and varying the front current, holding the back current at a second back constant and varying the front current, and increasing the front current from a third front constant to a fourth front constant while decreasing the back current from a third back constant to a fourth back constant in order to determine stable middle lines within each super-mode and wherein, having determined the stable middle lines, subsequent steps of varying the back current and/or the front current respectively comprise varying the respective current through a window of a plurality of incremental values along the stable middle lines and determining for which of the plurality of incremental values the power output is a minimum, and repeatedly incrementing each of the plurality of incremental values and re-determining the current value corresponding to the minimum output power within the window to determine a current value corresponding to a local minimum in the power output.

16. A method as claimed in claim 12, wherein, for a laser having more than three sections, step b) comprises determining midpoints between the current values corresponding to local minima in the power output to obtain stable middle points of operation of the laser and step e) includes storing data representative of such stable middle points together with the corresponding wavelength of emitted laser light in the look-up table and operational conditions for operating the frequencies between the stable middle point frequencies are determined by determining and storing in the look-up table the required values of phase current injected into the phase section of the laser and the required values of phase current are determined by holding the back and front currents constant successively at a first stable point and incrementing the phase current until a frequency of laser emission corresponding to a next stable point is reached and calculating what increments of phase current are required to step from the first stable point to the second stable point in desired frequency increments.

17. A method of controlling a laser characterised by:
a) applying currents (I_{P}, I_{G}, I_{R}) in step-wise increments to sections of the laser respectively;
b) measuring power output by the laser to determine values of the applied currents corresponding to respective stable operating conditions for which the laser emits radiation at wavelengths remote from mode boundaries of the laser;
c) determining the respective wavelength of the emitted radiation;
d) measuring variations in the applied currents required to cross a mode boundary such that the laser undergoes a mode jump to emit radiation at a wavelength significantly different from that under the respective stable operating condition;
e) storing in a first look-up table respective values of applied currents. (I_{P}, I_{G}, I_{R}) for which the laser emits radiation at wavelengths remote from mode boundaries, the corresponding wavelengths of the radiation and the variations in applied currents required to cross adjacent mode boundaries for use of the laser under the characterising conditions and state of ageing of the laser;
f) varying the applied currents, to cause predetermined incremental changes in wavelength of the emitted radiation, within the said mode boundaries, and storing further values of applied currents in a first of further look-up tables for the predetermined incremental change in wavelength for use of the first of further look up tables in place of the first look-up table as the wavelength of radiation emitted with currently used applied currents changes by more than a predetermined threshold change; and
g) repeating step f) a further plurality of times, to store further look-up tables other than the first further look-up table for use in place of the first further look-up table or of one of said other further look-up tables as the wavelength of radiation emitted with a currently used look-up table changes by more than a further predetermined threshold change; and
h) determining whether in use the wavelength of radiation emitted by the laser has varied from a characterising wavelength by more than a threshold variation and if so selecting and using the further look-up tables to restore the emitted wavelength to a wavelength within the threshold variation.

18. A method as claimed in claim 17, wherein step h) comprises measuring, at predetermined intervals of time, an offset in the phase current as generated by a frequency-locker feedback-control circuit connected to the laser, to determine whether the offset is excessive and in danger of causing a mode hop; and sufficient to require re-characterisation of the laser which condition may trigger an alarm and, if the offset is excessive but not requiring re-characterisation, identifying and using the further look-up tables stored when the laser was last characterised.

19. A method as claimed in claim 18, wherein the step of determining whether any change in the values is sufficient to require re-characterisation of the laser comprises determining whether the phase current offset is greater than a predetermined value or represents more than a predetermined percentage change.

20. A method as claimed in claim 18, wherein the frequency locker includes the graded refractive index lens.

21. A method as claimed in claim 18, wherein, the frequency locker includes a Fabry Perot etalon comprising mirrors embedded in slots in a waveguide.

22. A method as claimed in claim 1 of characterising a DS-DBR laser as if it were a collection of a plurality of conventional DBR lasers using an hysteresis property of such lasers.

23. A method as claimed in claim 1 of characterising a tunable laser containing one or more current tunable reflection gratings and a Fabry-Perot cavity wherein the spectra of the grating and a nearby cavity mode overlap to produce a selectable lasing wavelength, the method comprising the steps of:
a. analysing a resulting hysteresis of longitudinal mode boundaries for meander and span to reject defective lasers; and
b. identifying longitudinal mode middle lines for best operation to avoid mode hopping; and
c. producing a look-up table of operating currents for desired optical frequencies therefrom.

24. A characterising apparatus for a tuneable multi-section semiconductor laser comprising current drive means arranged for applying currents (I_{P}, I_{G}, I_{R}) in step-wise increments to sections of the laser respectively; power measuring means arranged for measuring power output by the laser to determine values of the applied currents corresponding to respective stable operating conditions for which the laser emits radiation at wavelengths remote from mode boundaries of the laser; and wavelength measuring means arranged for determining a respective wavelength of the emitted radiation; characterised in current measuring means arranged for measuring variations in the applied currents required to cross a mode boundary such that the laser undergoes a mode jump to emit radiation at a wavelength significantly different from that under the respective stable operating condition; and storage means storing in a first look-up table respective values of applied currents for which the laser emits radiation at wavelengths remote from mode boundaries, the corresponding wavelengths of the radiation and the variations in applied currents required to cross adjacent mode boundaries for use of the laser under the characterising conditions and state of ageing of the laser and storing further look-up tables for each of a plurality of predetermined incremental changes in wavelength respectively for use as the wavelength of radiation emitted changes by more than a predetermined threshold within the said mode boundaries.

25. An apparatus as claimed in claim 24, wherein the power measuring means comprises a first photodiode connectable to the laser by optical waveguide means.

26. An apparatus as claimed in claim 24, wherein the wavelength measuring means comprises a feature extraction filter connectable to the laser by optical waveguide means and a second photodiode connectable to an output of the feature extraction filter by optical waveguide means.

27. An apparatus as claimed in claim 26, wherein the feature extraction filter comprises a dielectric multilayer coating on a transparent substrate located in the optical waveguide means between the laser and the second photodiode.

28. An apparatus as claimed in claim 24, wherein the wavelength measuring means further comprises a first Fabry Perot etalon filter or Fizeau filter, having a first Free Spectral Range (FSR), connectable to the laser by optical waveguide means and a third photodiode connectable to an output of the first Fabry Perot etalon filter or Fizeau filter by optical waveguide means.

29. An apparatus as claimed in claim 28, wherein the first FSR is substantially 5 GHz.

30. An apparatus as claimed in claim 28, wherein the first Fabry Perot etalon filter comprises first and second spaced apart, flat response, dielectric mirrors located in the optical waveguide means between the laser and the third photodiode.

31. An apparatus as claimed claim 24, wherein the wavelength measuring means further comprises a second Fabry Perot etalon filter or Fizeau filter, having a second FSR different from the first FSR, connectable to the laser by optical waveguide means and a fourth photodiode connectable to an output of the second Fabry Perot etalon filter by optical waveguide means.

32. An apparatus as claimed in claim 31, wherein the second FSR is substantially 50 GHz.

33. An apparatus as claimed in claim 24, wherein the wavelength measuring means further comprises a second Fabry Perot etalon filter or Fizeau filter, having a second FSR and the first FSR and the second FSR are a same FSR between 50 GHz and 400 GHz and the first Fabry Perot etalon filter or Fizeau filter is out of phase by one quarter of the same FSR from the second Fabry Perot etalon filter or Fizeau filter so that the first and second filters are in quadrature.

34. An apparatus as claimed in claim 31, wherein the second Fabry Perot etalon filter comprises third and fourth spaced apart, flat response, dielectric mirrors located in the optical waveguide means between the laser and the fourth photodiode.

35. An apparatus as claimed in claim 24, wherein the wavelength measuring means further comprises a third Fabry Perot etalon filter, having a third FSR, connectable to the laser by optical waveguide means, and a fifth photodiode connectable to an output of the third Fabry Perot etalon filter, wherein the third FSR provides a local maximum in transmissivity at a same reference frequency as a local maximum in transmissivity provided by the first FSR.

36. An apparatus as claimed in claim 24, wherein at least some of the laser, feature extraction filter and first and second Fabry Perot etalon filters are interconnected by optical waveguide means to form a planar lightwave circuit on a substrate.

37. An apparatus as claimed in claim 36, wherein the optical waveguide means is a branched ridge optical waveguide.

38. An apparatus as claimed in claim 24 arranged for characterising a DS-DBR laser as if it were a collection of a plurality of conventional DBR lasers using a hysteresis property of such devices.

39. An apparatus as claimed in claim 24 arranged for characterising tunable lasers containing one or more current tunable reflection gratings and a Fabry-Perot cavity wherein a spectra of the one or more gratings and a mode of the nearby cavity overlap to produce a selectable lasing wavelength; and for analysing a resulting hysteresis of longitudinal mode boundaries for meander and span to detect defective lasers; and for identifying longitudinal mode middle lines for operation avoiding mode hopping to produce a look-up table of operating currents for desired optical frequencies.

40. A computer program comprising code means for characterising a tuneable multi-section semiconductor laser such that a wavelength of the laser changed by more than a threshold variation may be accommodated, by performing all the steps of:
a. applying currents (I_{P}, I_{G}, I_{R}) in step-wise increments to sections of the laser respectively;
b. measuring power output by the laser to determine values of the applied currents corresponding to respective stable operating conditions for which the laser emits radiation at wavelengths remote from mode boundaries of the laser;
c. determining the respective wavelength of the emitted radiation;
d. measuring variations in the applied currents required to cross a mode boundary such that the laser undergoes a mode jump to emit radiation at a wavelength significantly different from that under the respective stable operating condition;
e. storing in a first look-up table respective values of applied currents (I_{P}, I_{G}, I_{R}) for which the laser emits radiation at wavelengths remote from mode boundaries, the corresponding wavelengths of the radiation and the variations in applied currents required to cross adjacent mode boundaries for use of the laser under the characterising conditions and state of ageing of the laser;
f. varying the applied currents, to cause predetermined incremental changes in wavelength of the emitted radiation, within the said mode boundaries, and storing further values of applied currents in a first of further look-up tables for the predetermined incremental change in wavelength for use of the first of further look up tables in place of the first look-up table as the wavelength of radiation emitted with currently used applied currents changes by more than a predetermined threshold change; and
g. repeating step f) a further plurality of times, to store further look-up tables other than the first further look-up table for use in place of the first further look-up table or of one of said other further look-up tables as the wavelength of radiation emitted with a currently used look-up table changes by more than a further predetermined threshold change when the program is run on one or more computers.
